(19) United States
(12) Patent Application Publication
(10) Pub. No.: US 2018/0269230 A1
(43) Pub. Date: Sep. 20, 2018

(54) Thin Polysilicon For Lower Off-Capacitance Of A Radio Frequency (RF) Silicon-On-Insulator (SOI) Switch Field Effect Transistor (FET)

(71) Applicant: Newport Fab, LLC dba Jazz Semiconductor, Inc., Newport Beach, CA (US)

(72) Inventor: Roda Kanawati, Irvine, CA (US)

(21) Appl. No.: 15/459,488

(22) Filed: Mar. 15, 2017

(51) Int. Cl. H01L 27/12; H01L 29/49; H01L 29/423; H01L 21/84; H01L 23/528; H01L 27/092; H01Q 1/22

(52) U.S. Cl. CPC H01L 27/1203; H01L 29/4916; H01L 29/42376; H01Q 1/2283; H01L 23/5283; H01L 27/092; H01L 21/84

(57) ABSTRACT

A radio frequency (RF) switch includes a plurality of series-connected silicon-on-insulator (SOI) CMOS transistors fabricated in accordance with a semiconductor process having a first minimum line width (e.g., 0.18 microns). While the semiconductor process conventionally implements a polysilicon gate layer having a first thickness (e.g., 2000 Angstroms), each of the plurality of SOI CMOS transistors is fabricated with a polysilicon gate electrode having a second thickness, which is less than the first thickness. The reduced thickness of the polysilicon gate electrodes of the SOI CMOS transistors reduces the on-resistance and the off-capacitance of the associated RF switch.

### FIELD OF THE INVENTION

The present invention relates to a radio frequency (RF) switch including a plurality of silicon-on-insulator (SOI) CMOS transistors.

### RELATED ART

FIG. 1 is a circuit diagram of a conventional radio frequency (RF) circuit 100, including an antenna 101, an RF receiver switch 110, an RF receiver port 115, an RF transmitter switch 120 and an RF transmitter port 125. RF receiver switch 110 includes a plurality of high-voltage field effect transistors (FETs) 110₁-110_{N}, which are connected in series (in a stack). The stack of high voltage FETs 110₁-110_{N} is controlled to route RF signals from antenna 101 to receive port 115. Similarly, RF transmitter switch 120 includes a stack of high-voltage FETs 120₁-120_{N}, which are controlled to route RF signals from transmit port 125 to antenna 101. As used herein, an RF signal is defined as a signal having a frequency in the range of about 10 kHz to 50 GHz. The FETs used in the switch branch stack are large, typically 1-5 mm (millimeter) in total width. It is understood that FIG. 1 is a simplified schematic for illustrative purposes and that many features of a full RF switch product related to biasing, voltage balance, etc., are not shown.

Silicon-on-insulator (SOI) CMOS technologies are now the dominant platforms for creating best-in-class radio frequency switch (RFSW) products for handsets and other mobile devices. Thus, transistors 110₁-110_{N} and 120₁-120_{N} are typically implemented using SOI CMOS transistors. Such SOI CMOS transistors enable the associated RF switches 110 and 120 to transmit RF signals in the range of 0.5 GHz to 6 GHz with a high degree of linearity, while withstanding voltages of 40V to 70V and in an off-state. Because SOI CMOS technology uses standard CMOS technologies and standard cell libraries, RF switches that implement SOI CMOS transistors can be readily integrated into larger system-on-chip (SOC) devices, thereby minimizing fabrication costs. For example, transistors 110₁-110_{N} and 120₁-120_{N} and transistors associated with receive port 115 and transmit port 125 may be fabricated on the same integrated circuit chip.

As described herein, an SOI CMOS technology includes any process that can be used to fabricate SOI CMOS transistors. Thus, a process that can be used to integrate the fabrication of both SOI CMOS transistors and other types of transistors (e.g., SiGe BiCMOS transistors) is considered to be an SOI CMOS process.

For RF switch 110 (or 120), the on-resistance of the switch (R_{ON}) multiplied by the off-capacitance of the switch (C_{OFF}) is a key figure of merit, which dictates the ability to transmit RF power with low losses through on-state transistor stacks, while maintaining adequate isolation across off-state transistor stacks. The thin film SOI CMOS transistors are attractive for RF switch applications, because these transistors reduce the junction capacitance component of the off-capacitance value, C_{OFF}.

Typically, the off-state stacks of an RF switch need to hold off relatively high voltage RF signals (e.g., 40-70V). Consequently, RF switches are implemented with older generation SOI CMOS transistors having operating voltages in the 2.5 Volt-5 Volt range. These older generation SOI CMOS transistors are fabricated using process nodes with a minimum feature size of 0.18 microns or greater. In general, the gate length of each of transistors 110₁-110_{N} and 120₁-120_{N} must be about 0.18 microns or more to provide the required off-state isolation. Note that transistors fabricated using more advanced process nodes (e.g., a 0.13 micron process node) have lower operating voltages (e.g., 1.2 Volts or lower), and are typically not suitable for implementing an RF switch.

FIG. 2 is a cross-sectional view of a conventional SOI CMOS structure 200, which includes n-channel SOI CMOS transistor 201 and p-channel SOI CMOS transistor 202, which are fabricated using a conventional 0.18 micron SOI CMOS process node. Transistors similar to n-channel SOI CMOS transistor 201 can be used to implement each of transistors 110₁-110_{N} and 120₁-120_{N} of RF switches 110 and 120. Transistors similar to n-channel SOI CMOS transistor 201 and p-channel SOI CMOS transistor 202 can be used to implement circuitry found within receive port 115 and transmit port 125.

SOI CMOS transistors 201-202 are fabricated on a thin silicon layer 205, which is located on an insulator 204 (e.g., silicon oxide), which in turn, is located on a substrate 203 (e.g., monocrystalline silicon).

N-channel SOI CMOS transistor 201 includes an n-type source region 211 (which includes lightly doped source region 211A and source contact region 211B), an n-type drain region 212 (which includes lightly doped drain region 212A and drain contact region 212B), gate dielectric 215, polysilicon gate 217, dielectric sidewall spacers 219-220 and metal silicide regions 223-225. A p-type channel region 209 exists between the source region 211 and the drain region 212. Polysilicon gate 217 has a length L_{A} of 0.18 microns or greater, and a thickness T_{X} of about 2000 Angstroms. To implement a typical RF switch, polysilicon gate 217 may have a length L_{A} of about 0.28 microns.

Polysilicon gate electrode 217 is exposed during the implant of an n-type dopant into source/drain regions 211-212, such that polysilicon gate electrode 217 is doped to an n-type conductivity. When a logic high voltage (e.g., 2.5 Volts) is applied to polysilicon gate electrode 217, a depletion effect within the polysilicon results in the formation of an inversion layer within the polysilicon gate electrode 217, whereby a reduced voltage (e.g., 2.3 Volts) is applied at the channel region 209 of the transistor 201. This polysilicon depletion effect undesirably results in an increased on-resistance R_{ON} of transistor 201.

P-channel SOI CMOS transistor 202 includes a p-type source region 213 (which includes lightly doped source region 213A and source contact region 213B), a p-type drain region 214 (which includes lightly doped drain region 214A and drain contact region 214B), gate dielectric 216, polysilicon gate 218, dielectric sidewall spacers 221-222 and metal silicide regions 226-228. An n-type channel region 210 exists between the source region 213 and the drain region 214. Polysilicon gate 218 has the same thickness T_{X} as polysilicon gate 217. Polysilicon gate 218 has a length of 0.18 microns or greater. The length of polysilicon gate 218 is selected in view of the particular application of transistor 202.

A multi-layer interconnect structure 260 is fabricated over transistors 201-202, thereby providing electrical connections to these transistors (and other devices fabricated in the thin silicon layer 205). In the example illustrated, a pre-metal dielectric (PMD) structure 230 is formed over transistors 201-202. Tungsten (W) contacts 231, 232, 233 and 234 extend through the PMD layer 230 and contact the silicide regions 223, 225, 226 and 228, respectively, as illustrated. A first metal layer (M1), including aluminum traces 241-244, is formed over PMD layer 230. A dielectric structure 240 is formed over the PMD structure 230 and the first metal layer (M1). Tungsten vias 245-248 extend through the dielectric structure 240 to provide contact to aluminum traces 241-244, respectively, of the first metal layer.

Additional alternating metal layers, metal vias and insulating structures are formed over the dielectric structure 240 in a manner known to those in the art. For example, FIG. 2 illustrates aluminum traces 251-254 of a second metal layer (M2) formed over the dielectric structure 240.

The lengths, thicknesses and spacings of traces 231-234, traces 241-244, vias 245-248 and traces 251-255 contribute to the off-capacitances (C_{OFF}) of the associated RF switches 110 and 120. For example, capacitance C_{A} (between polysilicon gate 217 and source region 211), capacitance C_{B} (between polysilicon gate 217 and contact 231), capacitance C_{C} (between polysilicon gate 217 and M1 trace 241), capacitance C_{D} (between polysilicon gate 217 and M1 trace 242), capacitance C_{E} (between polysilicon gate 217 and contact 232), and capacitance C_{F} (between polysilicon gate 217 and drain region 212) all contribute to the off-capacitance (C_{OFF}) of transistor 217.

It would be desirable to have an improved SOI CMOS transistor for implementing an RF switch structure, and a method for fabricating the same. It would be desirable for the improved RF switch structure to have a reduced on-resistance R_{ON} and a reduced off-capacitance C_{OFF}. It would further be desirable if this improved RF switch structure can be fabricated using a process that is substantially consistent with existing conventional fabrication process nodes.

### SUMMARY

Accordingly, the present invention provides an RF switch that includes a plurality of SOI CMOS transistors having polysilicon gates with relatively small thicknesses. That is, the thickness of the polysilicon gate is thinner than the typical thickness of a polysilicon gate associated with the process used to fabricate the device.

In one embodiment, the SOI CMOS transistors of the RF switch are fabricated using a largely conventional SOI CMOS process. However, the thickness of the polysilicon layer (and therefore the thicknesses of the polysilicon gates of the associated transistors) is reduced with respect to a conventional SOI CMOS process. For example, a conventional 0.18 micron SOI CMOS process technology may typically use a polysilicon layer having a thickness of about 2000 Angstroms. In accordance with one embodiment, the 0.18 micron SOI CMOS process is modified to provide a polysilicon layer having a reduced thickness of about 1250 Angstroms. In an alternate embodiment, the 0.18 micron SOI CMOS process is modified to provide a polysilicon layer having a thickness in a range of about 1350 to about 1150 Angstroms. In yet another embodiment, the 0.18 micron SOI CMOS process is modified to provide a polysilicon layer having a thickness of less than about 1450 Angstroms. In another embodiment, the 0.18 micron SOI CMOS process is modified to provide a polysilicon layer having a thickness that is less than or equal to about 70% of the thickness of a conventional polysilicon layer used by the 0.18 micron SOI CMOS process.

The thin polysilicon gate of the SOI CMOS transistor advantageously exhibits a reduced contact-to-polysilicon capacitance, a reduced metal one (M1) to polysilicon capacitance and a reduced fringing capacitance (between the polysilicon and the source/drain regions of the SOI CMOS transistor), thereby resulting in a lower off-capacitance (C_{OFF}) of the associated RF switch. In addition, the thin polysilicon gate of the SOI CMOS transistor inhibits the polysilicon depletion effect, advantageously resulting in a lower on-resistance (R_{ON}) of the associated RF switch.

The present invention also includes methods for fabricating RF switches having SOI CMOS transistors with polysilicon gates having reduced thicknesses. The present invention will be more fully understood in view of the following description and drawings.

### BRIEF DESCRIPTION OF THE DRAWINGS

FIG. 1 is a circuit diagram of a conventional radio frequency (RF) circuit that includes conventional SOI CMOS transistors.

FIG. 2 is a cross-sectional view of a conventional SOI CMOS structure, which includes an n-channel SOI CMOS transistor and a p-channel SOI CMOS transistor, which are fabricated using a conventional 0.18 micron SOI CMOS process node.

FIG. 3 is a cross-sectional view of an SOI CMOS structure that includes reduced thickness polysilicon gates, in accordance with one embodiment of the present invention.

### DETAILED DESCRIPTION

In general, the present invention includes an RF switch that includes a plurality of n-channel SOI CMOS transistors connected in series. The n-channel SOI CMOS transistors are fabricated in accordance with a conventional SOI CMOS process node, with the exception of the formation of the polysilicon gate layer. In accordance with the present invention, the polysilicon gate layer is thinner than a polysilicon layer typically associated with the conventional SOI CMOS process node. For example, n-channel SOI CMOS transistors may be fabricated substantially in accordance with a 0.18 micron SOI CMOS process node. The polysilicon gate layer of a 0.18 SOI CMOS process node typically has thicknesses of about 2000 Angstroms. However, in accordance with the present invention, the polysilicon gate layer is fabricated to have a thickness less than about 1450 Angstroms. For example, the polysilicon gate layer may have a thickness in the range of about 1350 to 1150 Angstroms. In another embodiment, the polysilicon gate layer may have a thickness of about 1250 Angstroms. In another embodiment, the 0.18 micron SOI CMOS process is modified to provide a polysilicon gate layer having a thickness that is less than or equal to about 70% of the thickness of a conventional polysilicon gate layer used by the 0.18 micron SOI CMOS process. The thinner polysilicon gate layer results in associated SOI CMOS transistors having a lower off-capacitance (C_{OFF}) and a lower on-resistance (R_{ON}). As a result, an RF switch constructed from such SOI CMOS transistors advantageously exhibits a reduced R_{ON}×C_{OFF} value. The present invention is described in more detail below.

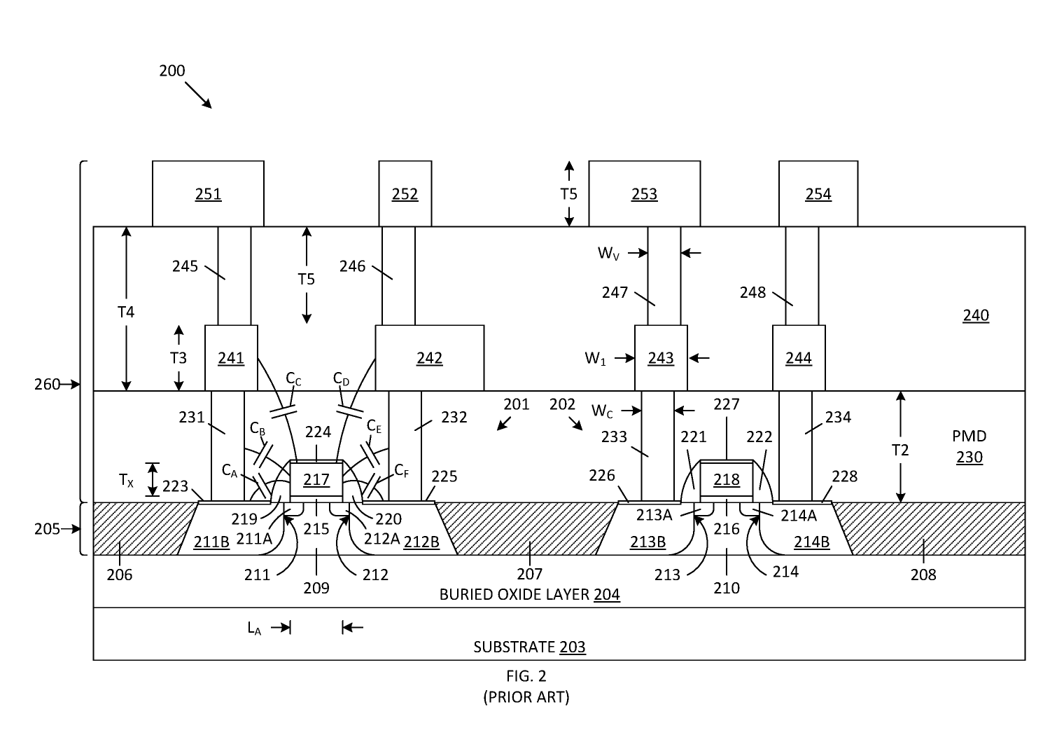

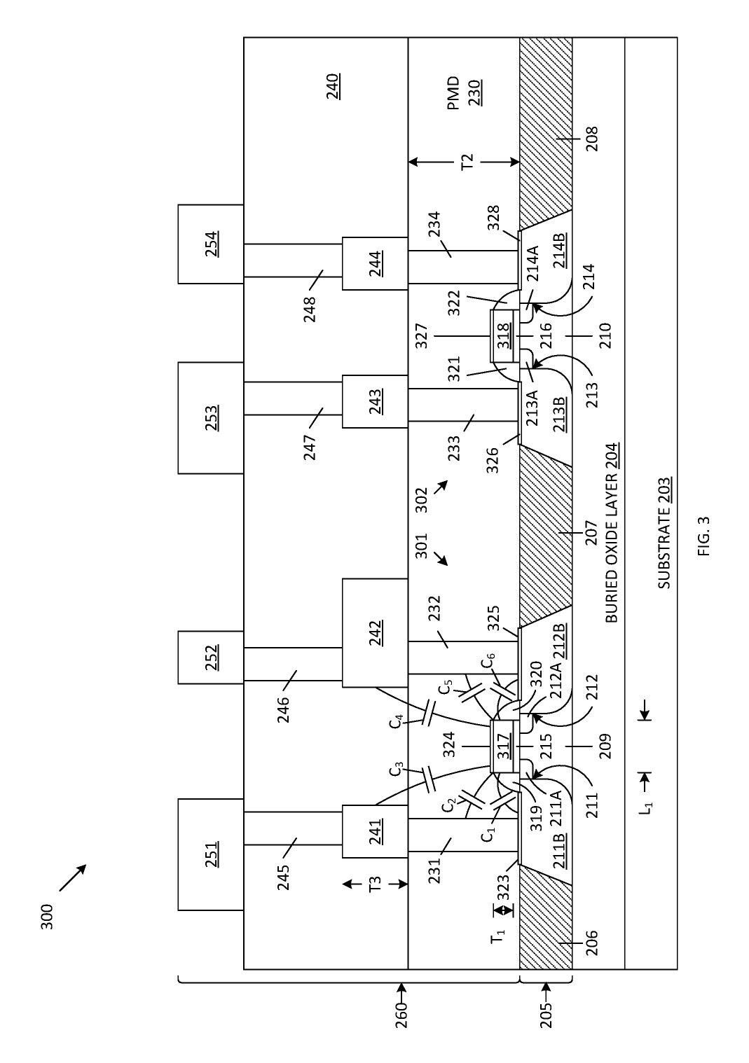

FIG. 3 is a cross-sectional view of an SOI CMOS structure 300 in accordance with one embodiment of the present invention. SOI CMOS structure 300 includes n-channel SOI CMOS transistor 301 and p-channel SOI CMOS transistor 302. Because transistors 301 and 302 are similar to transistors 201 and 202 (FIG. 2), similar elements in FIGS. 2 and 3 are labeled with similar reference numbers. Thus, transistors 301-302 are fabricated in a thin silicon layer 205, which is located on an insulator 204 (e.g., silicon oxide), which in turn, is located on a substrate 203 (e.g., monocrystalline silicon).

N-channel SOI CMOS transistor 301 includes an n-type source region 211 (which includes lightly doped source region 211A and source contact region 211B), an n-type drain region 212 (which includes lightly doped drain region 212A and drain contact region 212B) and gate dielectric 215. A p-type channel region 209 exists between the source region 211 and the drain region 212.

P-channel SOI CMOS transistor 302 includes a p-type source region 213 (which includes lightly doped source region 213A and source contact region 213B), a p-type drain region 214 (which includes lightly doped drain region 214A and drain contact region 214B) and gate dielectric 216. An n-type channel region 210 exists between the source region 213 and the drain region 214.

Notably, transistors 301 and 302 include polysilicon gate electrodes 317 and 318, respectively, which are formed from a relatively thin polysilicon layer. The polysilicon gate electrodes 317 and 318 are thinner than the conventional polysilicon gate electrodes 217 and 218 of transistor 201 and 202 (FIG. 2). In accordance with one embodiment, polysilicon gate electrodes 317 and 318 have a thickness T₁ in the range of about 1350 to 1150 Angstroms. In accordance with another embodiment, polysilicon gate electrodes 317-318 have a thickness T₁ of about 1250 Angstroms. The thickness T₁ of polysilicon gate electrodes 317-318 is selected to minimize the off-capacitance (C_{OFF}) and the on-resistance (R_{ON}) of the re-channel SOI CMOS transistor 301, while allowing this transistor 301 to meet the operating requirements of an RF switch (e.g., RF switch 110). Polysilicon gates 317 and 318 have lengths of at least about 0.18 microns. In one embodiment, polysilicon gate electrode 317 has a length L₁ of about 0.28 microns. The length L₁ is selected to provide a desired on-resistance and breakdown voltage of the associated transistor 301.

Dielectric sidewall spacers 319-320 and 321-322 are formed adjacent to gate electrodes 317 and 318, respectively, and metal silicide regions 323, 324, 325, 326, 327 and 328 are formed over source region 211, gate electrode 317, drain region 212, source region 213, gate electrode 318 and drain region 214, respectively. Multi-layer interconnect structure 260 (which includes pre-metal dielectric structure 230, contacts 231-234, first metal (M1) layer traces 241-244, conductive vias 245-248, inter-metal dielectric structure 240 and second metal (M2) layer traces 251-254) is formed over transistors 301-302. In the embodiments described herein, PMD structure 230 has a thickness T2 of about 4,000 to 10,000 Angstroms.

In accordance with one embodiment, transistors 301-302 and multi-layer interconnect structure 260 are fabricated in accordance with a conventional 0.18 micron SOI CMOS process node, with the exception of the polysilicon layer used to form the polysilicon gates 317-318. The polysilicon layer used to form polysilicon gates 317-318 is selected to have a thickness that is less than the thickness of a typical polysilicon layer in a conventional 0.18 micron SOI CMOS process node. For example, while the polysilicon layer in a conventional 0.18 micron SOI CMOS process node may have a typical thickness of about 2000 Angstroms (see, e.g., FIG. 2), the polysilicon layer used to form polysilicon gates 317-318 has a thickness less than about 1450 Angstroms in accordance with one embodiment of the present invention. In one embodiment, the thickness of the polysilicon layer used to form polysilicon gates 317-318 is in the range of about 1150 to 1350 Angstroms. In a particular embodiment, the thickness of the polysilicon layer used to form polysilicon gates 317-318 is in the range of about 1250 Angstroms.

Various parasitic capacitances C1-C6 are associated with polysilicon gate electrode 317. These parasitic capacitances include, for example, capacitance C₁ (between polysilicon gate 317 and source region 211), capacitance C₂ (between polysilicon gate 317 and contact 231), capacitance C₃ (between polysilicon gate 317 and M1 trace 241), capacitance C₄ (between polysilicon gate 317 and M1 trace 242), capacitance C₅ (between polysilicon gate 317 and contact 232), and capacitance C₆ (between polysilicon gate 317 and drain region 212). These parasitic capacitances C₁-C₆ all contribute to the off-capacitance (C_{OFF}) of transistor 317. The capacitances C₁-C₆ are dependent upon the lateral surface area of polysilicon gate 317. Similarly, the capacitances C_{A}-C_{F} are dependent upon the lateral surface area of polysilicon gate 217 (FIG. 2). The lateral surface area of polysilicon gate 317 is smaller than the lateral surface area of polysilicon gate 217, due to the reduced height T₁ of the polysilicon gate 317. Because the interconnect structure 260 is identical for transistors 201 and 301, the parasitic capacitances C₁-C₆ associated with polysilicon gate 317 are less than the parasitic capacitances C_{A}-C_{F} associated with polysilicon gate 217. As a result, the off-capacitance of transistor 301 (FIG. 3) is advantageously less than the off-capacitance of transistor 201 (FIG. 2). Note that p-channel transistor 302 will similarly exhibit a lower off-capacitance than p-channel transistor 202.

Polysilicon gate electrode 317 is exposed during the formation (e.g., implantation) of n-type source/drain regions 211-212, such that polysilicon gate electrode 317 is doped to an n-type conductivity. Within a relatively thick polysilicon gate electrode (e.g., polysilicon gate electrode 217), such n-type doping can result in the formation of an inversion layer within the gate electrode when a positive voltage is applied to the gate electrode (to turn on the transistor). As described above, this inversion layer results in the formation of a potential barrier within the gate electrode 217, such that the full voltage applied to the gate electrode is not applied to the channel region of the transistor. The reduced thickness T₁ of polysilicon gate electrode 317 results in a higher n-type dopant concentration within gate electrode 317 (when compared with the n-type dopant concentration within gate electrode 217), thereby inhibiting the formation of an inversion layer within the gate electrode 317 when a positive voltage is applied to the gate electrode 317 to turn on transistor 301. Elimination/reduction of the inversion layer results in a higher voltage being applied to the channel region 209 of transistor 301, effectively reducing the on-resistance of transistor 301. Thus, if a 2.5 Volt control voltage is applied to gate electrode 317, then the channel region 209 is biased to a voltage of about 2.5 Volts to turn on transistor 301.

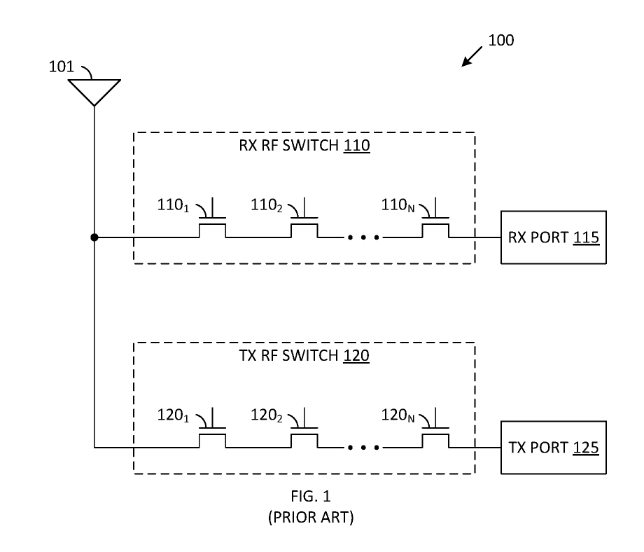

In accordance with one embodiment of the present invention, transistors similar to n-channel SOI CMOS transistor 301 are connected in series using the interconnect structure of FIG. 3 to form one or more RF switches (similar to RF switches 110 and 120 of FIG. 1). Transistors similar to n-channel SOI CMOS transistor 301 and p-channel SOI CMOS transistor 302 can also be connected using the interconnect structure of FIG. 3 to implement other circuitry associated with the RF switches (e.g., circuitry similar to that found within receive port 115 and transmit port 125 of FIG. 1).

Although the invention has been described in connection with several embodiments, it is understood that this invention is not limited to the embodiments disclosed, but is capable of various modifications, which would be apparent to a person skilled in the art. Thus, the invention is limited only by the following claims.

1. A radio frequency (RF) switch comprising:
a plurality of silicon-on-insulator (SOI) CMOS transistors, each including a polysilicon gate electrode having a first thickness and a first length, wherein the first length is at least about 0.18 microns and defines a length of a channel of the transistor, and wherein the first thickness is less than 1450 Angstroms.

2. The RF switch of claim 1, wherein the first thickness is about 1150 to 1350 Angstroms.

3. The RF switch of claim 1, wherein the first thickness is about 1250 Angstroms.

4. The RF switch of claim 1, further comprising a pre-metal dielectric layer formed over the plurality of SOI CMOS transistors, wherein the pre-metal dielectric layer has a thickness of about 4,000 to 10,000 Angstroms.

5. (canceled)

6. (canceled)

7. (canceled)

8. (canceled)

9. (canceled)

10. (canceled)

11. A radio frequency (RF) switch comprising:
a plurality of silicon-on-insulator (SOI) CMOS transistors fabricated in accordance with a semiconductor process having a first minimum line width, wherein the semiconductor process conventionally implements a polysilicon gate layer having a first thickness, wherein each of the plurality of SOI CMOS transistors is fabricated with polysilicon gate electrodes having a second thickness, less than the first thickness; and
an interconnect structure that couples the plurality of SOI CMOS transistors in series to form the RF switch.

12. The RF switch of claim 11, wherein the second thickness is less than about 70 percent of the first thickness.

13. The RF switch of claim 11, wherein the first minimum line width is 0.18 microns, and the second thickness is less than 1450 Angstroms.

14. The RF switch of claim 13, wherein the first thickness is about 2000 Angstroms.

15. The RF switch of claim 13, wherein the second thickness is about 1150 to 1350 Angstroms.

16. The RF switch of claim 13, wherein the second thickness is about 1250 Angstroms.

17. The RF switch of claim 11, wherein conventional polysilicon gate electrodes fabricated in accordance with the semiconductor process have the first thickness and a first dopant concentration, and wherein the polysilicon gate electrodes having the second thickness have a second dopant concentration, greater than the first dopant concentration.
